(19) United States
(12) Patent Application Publication
(10) Pub. No.: US 2025/0379034 A1
(43) Pub. Date: Dec. 11, 2025

(54) SYSTEMS AND METHODS FOR CALIBRATING RF GENERATORS IN A SIMULTANEOUS MANNER

(71) Applicant: Lam Research Corporation, Fremont, CA (US)

(72) Inventors: John C. Valcore, Worthington, OH (US); Adrian Esteban Sapio, Spicewood, TX (US); Travis Joseph Wong, Oakland, CA (US)

(21) Appl. No.: 18/877,966

(22) PCT Filed: Jun. 23, 2023
(86) PCT No.: PCT/US2023/069005

§ 371 Date: Dec. 20, 2024

Related U.S. Application Data
(60) Provisional application No. 63/355,940, filed on Jun. 27, 2022.

(51) Int. Cl. H01J 37/32

(52) U.S. Cl. CPC H01J 37/32183; H01J 37/3299

(57) ABSTRACT

Systems and methods for calibrating radio frequency (RF) generators are described. One of the methods includes receiving a plurality of analog measurement signals from a plurality of RF sensors to output a plurality of digital signals. The plurality of analog signals are received by an analytical controller. The method further includes calibrating, in a simultaneous manner, the RF generators based on the plurality of digital signals. The RF generators are calibrated by a process controller.

### FIELD

The present embodiments relate to systems and methods for calibrating radio frequency (RF) generators in a simultaneous manner.

### BACKGROUND

In general, in a plasma system, a radio frequency (RF) generator is coupled to a match network, which is coupled to a plasma chamber. The RF generator generates an RF signal and supplies the RF signal via the match network to the plasma chamber for processing a wafer within the plasma chamber. In addition, one or more process gases are supplied to the plasma chamber to generate plasma for processing the wafer. During processing of the wafer, it is desirable that the RF generator provides RF power of the RF signal according to a set point.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for calibrating radio frequency (RF) generators in a simultaneous manner. It should be appreciated that the present embodiments can be implemented in numerous ways, e.g., a process, an apparatus, a system, a device, or a method on a computer readable medium. Several embodiments are described below.

In one embodiment, a system for calibrating RF generators is described. The system includes a first RF generator coupled via a first RF cable to a first input of an impedance matching circuit and a second RF generator coupled via a second RF cable to a second input of the impedance matching circuit. The first input of the impedance matching circuit is coupled to a first RF sensor. Also, the second input of the impedance matching circuit is coupled to a second RF sensor. The system further includes a process controller, and an analytical controller coupled to the process controller. The analytical controller is coupled to the first and second RF sensors. The analytical controller receives a plurality of analog measurement signals from the first and second RF sensors to output a plurality of digital signals. The process controller receives the plurality of digital signals to calibrate the first and second RF generators.

In an embodiment, a system for calibrating RF generators is described. The system includes a first RF generator coupled via a first RF cable to a first input of a first impedance matching circuit, a second RF generator coupled via a second RF cable to a second input of the first impedance matching circuit, and a third RF generator coupled via a third RF cable to an input of a second impedance matching circuit. The first input of the first impedance matching circuit is coupled to a first RF sensor. Also, the second input of the first impedance matching circuit is coupled to a second RF sensor, and the input of the second impedance matching circuit is coupled to a third RF sensor. The system further includes a process controller, and an analytical controller coupled to the process controller. The analytical controller is coupled to the first, second, and third RF sensors. The analytical controller receives a plurality of analog measurement signals from the first, second, and third RF sensors to output a plurality of digital signals. The process controller receives the plurality of digital signals to calibrate the first, second, and third RF generators.

In an embodiment, a method for calibrating RF generators, such as two RF generators or three RF generators, is described. The method includes receiving a plurality of analog measurement signals from a plurality of RF sensors to output a plurality of digital signals. The plurality of analog signals are received by an analytical controller. The method further includes calibrating, in a simultaneous manner, the RF generators based on the plurality of digital signals. The RF generators are calibrated by a process controller.

In an embodiment, a method for determining ideal amplitude values is described. The method includes determining an average frequency of one of a plurality of analog measurement signals. The average frequency is determined for a predetermined number of cycles of the one of the plurality of analog measurement signals. The method further includes determining, for a cycle of the one of the plurality of analog measurement signals, a time of occurrence of a first threshold crossing of the one of the plurality of analog measurement signals. The cycle occurs after the predetermined number of cycles. The method further includes determining, based on the average frequency and the time of occurrence of the first threshold crossing, a first phase of a first sample point. The first sample point is a first measured value of the one of the plurality of analog measurement signals during a first half of the cycle. The method includes determining a first correction function from a first predetermined phase and the first phase, determining a first ideal amplitude value of the one of the plurality of analog measurement signals based on the first correction function, and controlling an RF generator based on the first ideal amplitude value.

In one embodiment, the systems and methods described herein can be utilized for any maximum, minimum, or amplitude measurement of any sine wave of a measurement signal. An accurate measurement of amplitude is obtained from a small number of wave periods of the measurement signal. When a fundamental tone, such as periodicity, of the measurement signal is known from the small number of wave periods, then the accurate amplitude can be calculated by substituting the measured periodicity with an actual or predefined periodicity enabling only a single period to occur to determine an accurate maximum, minimum, or another amplitude by the end of the single period.

In one embodiment, the systems and methods described herein can be used for an arbitrary periodic signal, such as the measurement signal, with an explicitly defined edge, and an ideal phase to determine a maximum amplitude or a minimum amplitude relative to the explicitly defined edge. As an example, for the arbitrary periodic signal, the maximum or minimum amplitude occurs at a phase that specific to an explicit periodic signal of interest. In the example, the phase is not 90 degrees or 270 degrees. Moreover, in the example, for the arbitrary periodic signal, the explicitly defined edge does not cross zero but instead crosses a specific threshold, such as a magnitude. As another example, for the arbitrary periodic signal, the maximum amplitude occurs at the 90 degree phase and the minimum amplitude occurs at the 270 degree phase.

Some advantages of the herein described systems and methods include calibrating multiple RF generators in a simultaneous manner, such as within the same time period or the same time frame. The RF generators are coupled to multiple RF sensors. Measurement information from the RF sensors is received by an analytical controller and converted from an analog format to a digital format to output digital signals. The digital signals are provided to a process controller for analyzing the digital signals. The processor controller calibrates the RF generators based on the digital signals. By calibrating the RF generators within the same time period, time is saved compared to when the RF generators are calibrated consecutively. In addition, when the RF generators are calibrated in the simultaneous manner, the RF generators are coupled to a plasma chamber via one or more impedance matching networks. As such, any fault in a component of a plasma tool having the plasma chamber, the RF generators, and the impedance matching networks can be determined in the simultaneous manner.

Further advantages of the herein described systems and methods include correcting a first amplitude, such as a maximum amplitude, of a measurement signal and a second amplitude, such as a minimum amplitude, of the measurement signal based on information provided by a single cycle of the measurement signal. Once an average frequency of the measurement signal is determined, a phase, within the single cycle, at which the first amplitude occurs and a phase, within the single cycle, at which the second amplitude occurs are determined. The phases are compared to corresponding ideal phases to determine first and second phase correction functions. A first ideal amplitude value, such as an ideal maximum amplitude, is determined to be a sample at a sum of the phase at which the first amplitude occurs and the first correction function. Also, a second ideal amplitude value, such as an ideal minimum amplitude, is determined to be a sample at a sum of the phase at which the second amplitude occurs and the second correction function. Instead of the first and second amplitudes, the first and second ideal amplitude values are provided to the process controller to calibrate the RF generators within the same time period. As such, applying the information within the single cycle to correct the first and second amplitudes saves time.

Additional advantages of the herein described herein systems and methods include reducing an amount of time for calibrating the RF generators in a simultaneous manner. Due to the simultaneous calibration in which the RF generators are operated together within the same time period, such as simultaneously, a reduced window of time is used for the RF generators to be calibrated. In addition, by determining the first and second ideal amplitude values from a single periodic wave of the measurement signal, additional time savings is achieved. It should be noted that the method for determining the first and second ideal amplitude values in a fewest number of periods of a periodic signal enables measurement of a behavior of a first one of the RF generators within a fractional period of a measurement signal associated with a second one of the RF generators. If the determination of the first and second ideal amplitude values takes a large number of time periods of the periodic signal associated with the first one of the RF generators, it is difficult to determine a behavior of the first one of the RF generators within the fractional period of the second one of the RF generators.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system for calibrating radio frequency (RF) generators.

FIG. 2 is a graph to illustrate a method for calibrating one or more RF generators.

FIG. 3 is a diagram of an embodiment of a system to illustrate a removal of sensors from the system of FIG. 1 after calibrating the RF generators of the system.

FIG. 4 is a graph to illustrate an analysis by a processor of a process controller of measured information within multiple digital signals received from an analytical controller.

FIG. 5 is a diagram of an embodiment of a system to illustrate that calibration of an RF generator is more time consuming than the calibration of the RF generators of the system of FIG. 1 within a prearranged time period.

FIG. 6 is a graph of a measurement signal to illustrate a method for calculation of an average frequency.

FIG. 7 is a diagram to illustrate a method for determining an ideal maximum amplitude and an ideal minimum amplitude of a measurement signal to correct an error created by an analog-to-digital converter (ADC) of the analytical controller during converting the measurement signal from an analog format to a digital format.

### DETAILED DESCRIPTION

The following embodiments describe systems and methods for calibrating radio frequency (RF) generators in a simultaneous manner. It will be apparent that the present embodiments may be practiced without some or all of these specific details. In other instances, well known operations have not been described in detail in order not to unnecessarily obscure the present embodiments.

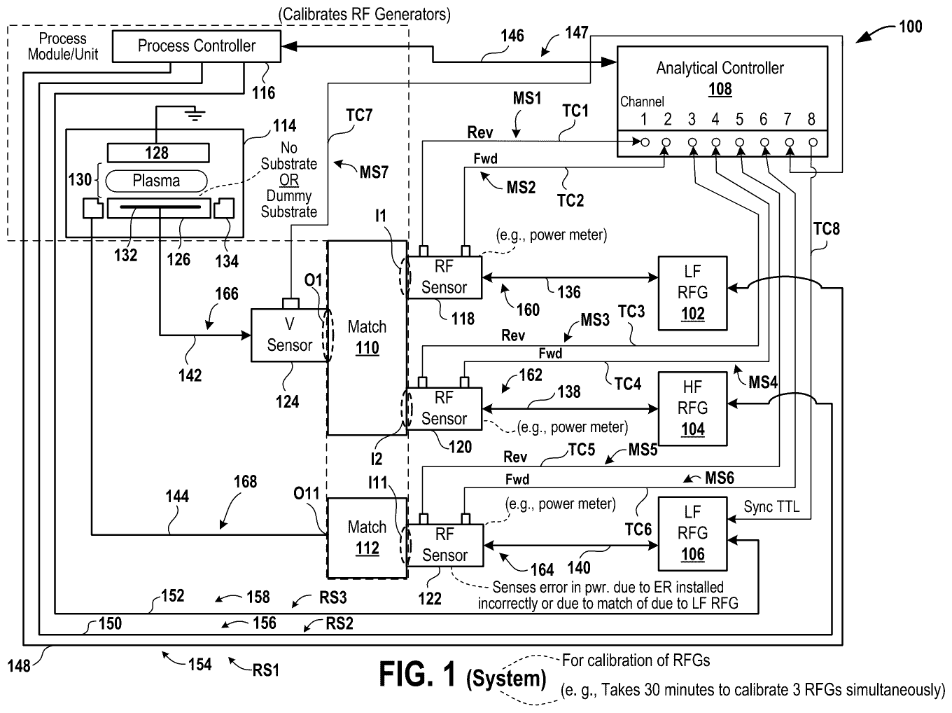

FIG. 1 is a diagram of an embodiment of a system 100 for calibrating RF generators 102, 104, and 106 in a simultaneous manner. The system 100 is sometimes referred to herein as a plasma system or a plasma tool. The system 100 includes the RF generators 102, 104, and 106, an analytical controller 108, a match 110, a match 112, a plasma chamber 114, a process controller 116, RF sensors 118, 120, and 122, and a voltage sensor 124. As an example, the match 110 has a separate housing from a housing of the match 112.

Each RF generator 102 and 106 operates at a low frequency (LF). Examples of the low frequency include is a frequency ranging from and including 400 kilohertz (kHz) to 2 megahertz (MHz). To illustrate, the low frequency is a baseline frequency or a fundamental frequency of 400 kHz. Moreover, the RF generator 104 operates at a high frequency (HF). Examples of high frequency include frequencies ranging from and including 60 megahertz (MHz) to 120 MHz. For example, the high frequency is a baseline frequency or a fundamental frequency of 60 MHz or 100 MHz. The high frequency is greater than the low frequency. For example, the low frequency is 400 kHz and the high frequency is 60 MHz. It should be noted that each RF generator 102 and 104 is sometimes referred to herein as an LF RF generator and the RF generator 106 is sometimes referred to herein as an HF RF generator.

As an example, the analytical controller 108 includes an analog-to-digital converter (ADC), a processor, and a memory device. The ADC is coupled to the processor of the analytical controller 108 and the processor is coupled to the memory device of the analytical controller 108. As an example, a processor, as used herein, can be an application specific integrated circuit (ASIC), a central processor of the analytical controller 108 (CPU), a field programmable gate array (FPGA), a programmable logic device (PLD), an integrated controller, or a microcontroller. Examples of a memory device, as used herein, include a read-only memory (ROM) and a random access memory (RAM). To illustrate, the memory device is a flash memory or a redundant array of independent discs (RAID). Further, as an example, the process controller 116 includes a processor and a memory device. The processor of the process controller 116 is coupled to the memory device of the process controller 116.

Examples of a match include an impedance matching circuit or an impedance matching network. For example, the match is a series of circuit components, such as capacitors, inductors, and resistors. The circuit components are coupled to each other. To illustrate, two of the circuit components are coupled to each other in a series or in parallel.

An example of an RF sensor, as used herein, includes a power meter or a power sensor. To illustrate, the power meter measures forward power and reverse power. To further illustrate, the forward power of an RF signal generated by an RF generator is power supplied by the RF generator via a match to the plasma chamber 114, and reverse power is power reflected from the plasma chamber 114 to the RF generator via the match. Reverse power is sometimes referred to herein as reflected power.

The plasma chamber 114 includes a substrate support 126, such as an electrostatic chuck (ESC). The plasma chamber 114 further includes an upper electrode 128 that is located above the substrate support 126 to form a gap 130 between the upper electrode 128 and the substrate support 126. The upper electrode 128 faces the substrate support 126. A lower electrode 132, embedded within the substrate support 126, is made from a metal, such as aluminum or an alloy of aluminum. The substrate support 126 is made from the metal and from a ceramic, such as aluminum oxide (Al₂O₃). The upper electrode 128 is fabricated from the metal and is coupled to a ground potential.

The plasma chamber 114 also includes an edge ring 134, such as a tunable edge sheath (TES) ring, which surrounds the substrate support 126. As an example, the edge ring 134 is fabricated from a conductive material, such as silicon, boron doped single crystalline silicon, silicon carbide, an alloy of silicon, or a combination thereof. It should be noted that the edge ring 134 has an annular body, such as a circular body, or ring-shaped body, or dish-shaped body. To illustrate, the edge ring 134 has an inner radius and an outer radius, and the inner radius is greater than a radius of the substrate support 126. An example of the plasma chamber 114 is a capacitively coupled plasma (CCP) chamber.

The RF generator 102 is coupled to an input I1 of the match 110 via an RF cable 136 and the RF sensor 118, the RF generator 104 is coupled to an input I2 of the match 110 via another RF cable 138 and the RF sensor 120, and the RF generator 106 is coupled to the an input I11 of the match 112 via an RF cable 140 and the RF sensor 122. The RF sensor 118 is coupled to the input I1, the RF sensor 120 is coupled to the input I2, and the RF sensor 122 is coupled to the input I11. For example, during a prearranged time period in which two or more of the RF generators 102, 104, and 106 are calibrated in the simultaneous manner, the RF sensor 118 remains coupled to a first port, of the match 110, at which the RF cable 136 is connected, the RF sensor 120 remains coupled to a second port, of the match 110, at which the RF cable 138 is connected, and the RF sensor 122 remains coupled to a port, of the match 112, at which the RF cable 140 is connected. In the example, the RF sensor 120 is not coupled to the match 110 after the RF sensor 118 is decoupled from the match 110. Also, in the example, the RF sensor 122 is not coupled to the match 112 after the RF sensor 120 is decoupled from the match 110. Rather, in the example, the RF sensors 118, 120, and 122 remain coupled to the matches 110 and 112 within the same prearranged time period. An example of an input is a port. An output O1 of the match 110 is coupled via an RF transmission line 142 to the lower electrode 132 and an output O11 of the match 112 is coupled via an RF transmission line 144 to the edge ring 134.

An example of an RF transmission line includes an RF rod that is surrounded by an RF tunnel, with an insulator between the RF rod and the RF tunnel. Another example of an RF transmission line includes a combination of one or more RF straps, the RF rod, and the RF tunnel. In the example, the one or more RF straps are coupled to the RF rod.

A port of each RF sensor 118 through 122 is coupled via a respective transfer cable to the analytical controller 108. For example, a first port of the RF sensor 118 is coupled via a transfer cable TC1 to a channel 1 of the analytical controller 108, a second port of the RF sensor 118 is coupled via a transfer cable TC2 to a channel 2 of the analytical controller 108. Also, in the example, a first port of the RF sensor 120 is coupled via a transfer cable TC3 to a channel 3 of the analytical controller 108 and a second port of the RF sensor 120 is coupled via a transfer cable TC4 to a channel 4 of the analytical controller 108. Further, in the example, a first port of the RF sensor 122 is coupled via a transfer cable TC5 to a channel 5 of the analytical controller 108 and a second port of the RF sensor 122 is coupled via a transfer cable TC6 to a channel 6 of the analytical controller 108. An example of a transfer cable is a cable for transferring an analog signal in a parallel manner, or a serial manner, or using a universal serial bus (USB) protocol.

The voltage sensor 124 is coupled via a transfer cable TC7 to a channel 7 of the analytical controller 108. The analytical controller 108 includes a channel 8, which is coupled via a transfer cable TC8 to the LF RF generator 106. The analytical controller 108 sends a transistor-transistor logic (TTL) signal, such as a clock signal, via the transfer cable TC8 to the LF RF generator 106. Also, the processor of the analytical controller 108 is coupled via a transfer cable 146 to the processor of the process controller 116. The process controller 116 is coupled via a transfer cable 148 to the LF RF generator 102. Also, the process controller 118 is coupled via a transfer cable 150 to the HF RF generator 104 and is coupled via a transfer cable 152 to the LF RF generator 106.

There is no substrate placed on a top surface of the substrate support 126. An example of the substrate includes a semiconductor wafer. The processor of the process controller 116 generates and sends a recipe signal 154 via the transfer cable 148 to the LF RF generator 102. As an example, a recipe signal, sent to an RF generator includes a power level and a frequency level of operation of the RF generator. Each power level includes one or more power values. Similarly, the processor of the process controller 116 generates and sends a recipe signal 156 via the transfer cable 150 to the HF RF generator 104, and generates and sends a recipe signal 158 via the transfer cable 152 to the LF RF generator 106. A digital signal processor (DSP) of each RF generator 102, 104, and 106 stores information, such as the respective power level and the respective frequency level, received within the respective one of the recipe signals 154, 156, and 158 in a respective memory device of the RF generator. Moreover, the processor of the process controller 116 sends a trigger signal via each of transfer cables 148, 150, and 152 to the respective one of the RF generators 102, 104, and 106.

Upon receiving the trigger signal, each RF generator 102, 104, and 106 generates a respective RF signal according to the information within the respective recipe signal received from the process controller 116. For example, the RF generator 102 generates an RF signal 160 having the power level and the frequency level received within the recipe signal 154, the RF generator 104 generates an RF signal 162 having the power level and the frequency level received within the recipe signal 156, and the RF generator 106 generates an RF signal 164 having the power level and the frequency level received within the recipe signal 158. It should be noted that the RF signals 160 through 164 are generated simultaneously and are not being generated consecutively to facilitate calibration of the RF generators 102 through 106 in the simultaneous manner.

The match 110 receives the RF signals 160 and 162, and matches an impedance of a load coupled to the output O1 with an impedance of multiple sources coupled to the inputs I1 and I2 to modify impedances of the RF signals 160 and 162. An example of the sources coupled to the inputs I1 and I2 include the RF cables 136 and 138, and the RF generators 102 and 104. An example of the load coupled to the output O1 includes the RF transmission line 142 and the plasma chamber 114. Also, the impedances of the RF signals 160 and 162 are modified to output a modified RF signal 166. The modified RF signal 166 is sent from the output O1 to the lower electrode 132.

Similarly, the match 112 receives the RF signal 164, and matches an impedance of a load coupled to the output O11 with an impedance of a source coupled to the input I11 to modify an impedance of the RF signal 164. An example of the source coupled to the input I11 includes the RF cable 140 and the RF generator 106, and an example of the load coupled to the output O11 includes the RF transmission line 144 and the plasma chamber 114. The impedance of the RF signal 164 is modified to output a modified RF signal 168. The modified RF signal 168 is sent from the output O11 to the edge ring 134. As an example, the modified RF signals 166 and 168 are simultaneously received by the plasma chamber 114 to facilitate the calibration of the RF generators 102 through 106 in the simultaneous manner.

When the RF signals 160, 162, and 164 are supplied to the matches 110 and 112 simultaneously, each of the RF sensors 118, 120, and 122 measures forward power and reverse power to output respective measurement signals, and sends the measurement signals to the processor of the analytical controller 108. For example, the RF sensor 118 measures forward power at the input I1 to output a measurement signal MS2, measures reverse power at the input I1 to output a measurement signal MS1, sends the measurement signal MS1 via the transfer cable TC1 and the channel 1 to the processor of the analytical controller 108, and sends the measurement signal MS2 via the transfer cable TC2 and the channel 2 to the processor of the analytical controller 108. In the example, the RF sensor 120 measures forward power at the input I2 to output a measurement signal MS4, measures reverse power at the input I2 to output a measurement signal MS3, sends the measurement signal MS3 via the transfer cable TC3 and the channel 3 to the processor of the analytical controller 108, and sends the measurement signal MS4 via the transfer cable TC4 and the channel 4 to the processor of the analytical controller 108. Further, in the example, the RF sensor 122 measures forward power at the input I11 to output a measurement signal MS6, measures reverse power at the input I11 to output a measurement signal MS5, sends the measurement signal MS5 via the transfer cable TC5 and the channel 5 to the processor of the analytical controller 108, and sends the measurement signal MS6 via the transfer cable TC6 and the channel 6 to the processor of the analytical controller 108. Moreover, in the example, the voltage sensor 124 measures voltage at the output O1 to output a measurement signal MS7, and sends the measurement signal MS7 via the transfer cable TC7 and the channel 7 to the processor of the analytical controller 108. To illustrate, the measurement signals MS1 through MS7 are simultaneously sent from the RF sensors 118 through 122 and the voltage sensor 124 to the analytical controller 108.

The ADC of the analytical controller 108 receives the measurement signals MS1 through MS7 received via the channels 1 through 7 and converts each of the measurement signals MS1 through MS7 from analog format to a digital format to output multiple digital signals 147. For example, the digital signals include a first digital signal generated based on the measurement signal MS1, a second digital signal generated based on the measurement signal MS2, a third digital signal generated based on the measurement signal MS3, a fourth digital signal generated based on the measurement signal MS4, a fifth digital signal generated based on the measurement signal MS5, a sixth digital signal generated based on the measurement signal MS6, and a seventh digital signal generated based on the measurement signal MS7. To illustrate, the ADC simultaneously converts the measurement signals MS1 through MS7 from the analog format to the digital format. To further illustrate, the ADC applies time division multiplexing to convert the measurement signals MS1 through MS7 from the analog format to the digital format. To yet further illustrate, the ADC converts a first portion of the measurement signal MS1, then converts a first portion of the measurement signal MS3, then converts a second portion of the measurement signal MS1, and then converts a second portion of the measurement signal MS3. As an example, the processor of the analytical controller 108 stores correspondence information within the memory device of the analytical controller 108. For example, the processor of the analytical controller 108 stores, within the memory device of the analytical controller 108, a one-to-one correspondence between each digital power value of the measurement signals MS1 through MS7 and a time at which the digital power value is output from the ADC.

Also, the ADC stores the measurement signals MS1 through MS7 within the memory device of the analytical controller 108. Moreover, the processor of the analytical controller 108, determines, based on the clock signal, a time at which each power value of each of the measurement signals MS1 through MS7 is received from the sensors 118 through 124. The digital signals 147 include measured information, such as the forward and reverse powers indicated by the measurement signals MS1 through MS6 and the voltage indicated by the measurement signal MS7. An example of the forward powers include multiple forward power levels and an example of the reverse powers include multiple reverse power levels. The ADC sends the digital signals 147 to the processor of the analytical controller 108.

The processor of the analytical controller 108 indicates, based on the channels, that a respective combination of the digital signals 147 is received from a respective input of a match. For example, the processor of the analytical controller 108 includes an identity of the input I1 of the match 110 within a set of the digital signals 147 that are output based on the measurement signals MS1 and MS2 upon determining that the MS1 and MS2 are received from the channels C1 and C2. In the example, the processor of the analytical controller 108 includes an identity of the input I2 of the match 110 within a set of the digital signals 147 that are output based on the measurement signals MS3 and MS4 upon determining that the measurement signals MS3 and MS4 are received from the channels C3 and C4. Further, in the example, the processor of the analytical controller 108 includes an identity of the input I11 of the match 112 within a set of the digital signals 147 that are output based on the measurement signals MS5 and MS6 upon determining that the measurement signals MS5 and MS6 are received from the channels C5 and C6. Also, in the example, the processor of the analytical controller 108 includes an identity of the output O1 of the match 110 within one of the digital signals 147 that is output based on the measurement signal MS7 upon determining that the measurement signal MS7 is received from the channel C7. The indication of a respective input or the respective output of a match, such as the match 110 or 112, is an example of match information.

The processor of the analytical controller 108 sends the digital signals 147 having the identities of the inputs I1, I2, and I11 and the output O1 via the transfer cable 146 to the processor of the process controller 116. For example, the digital signals 147 are sent within a predetermined time range, such as at the same time or substantially at the same time, to facilitate calibration of two or more of the RF generators 102, 104, and 106 within the prearranged time window. The processor of the process controller 116 receives the digital signals 147, stores the measured information and the match information indicated by the digital signals 147 in the memory device of the process controller 116, and determines, based on the identities I1, I2, and I11 and O1, whether to calibrate two or more of the RF generators 102 through 106 within the prearranged time period. For example, the processor of the processor receives the digital signals 147 simultaneously or substantially simultaneously from the analytical controller 108. In the example, the processor of the process controller 116 identifies, based on the identity of the input I1, received within the digital signals 147 that the input I1 is coupled to the LF RF generator 102. In the example, the processor accesses a correspondence between the input I1 and the LF RF generator 102 from the memory device of the process controller 116. Further, in the example, the processor calculates delivered power from the forward and reverse powers at the input I1, and determines whether the delivered power satisfies a first predetermined threshold, such as a range of power values. To illustrate, the processor computes the delivered power as a difference between the forward power and the reverse power. In the example, upon comparing the delivered power with the first predetermined threshold and determining that the delivered power is less than the first predetermined threshold, the processor controls the RF generator 102 to increase supplied power of the RF signal 160 to calibrate the RF generator 102 until the delivered power is within the first predetermined threshold. To illustrate, to control the RF generator 102, the processor increases the power level sent previously within the recipe signal 154 to output an increased power level and sends the increased power level within a recipe signal RS1 via the transfer cable 148 to the LF RF generator 102. In the example, on the other hand, upon comparing the delivered power with the first predetermined threshold and determining that the delivered power is greater than the first predetermined threshold, the processor controls the RF generator 102 to decrease supplied power of the RF signal 160 to calibrate the RF generator 102 until the delivered power is within the first predetermined threshold. To illustrate, the processor decreases the power level sent previously within the recipe signal 154 to output a decreased power level and sends the decreased power level within the recipe signal RS1 via the transfer cable 148 to the LF RF generator 102.

Continuing with the example, the processor of the process controller 116 identifies, based on the identity of the input I2, received within the digital signals 147 that the input I2 is coupled to the HF RF generator 104. In the example, the processor accesses a correspondence between the input I2 and the HF RF generator 104 from the memory device of the process controller 116. Further, in the example, the processor calculates delivered power from the forward and reverse powers at the input I2, and determines whether the delivered power satisfies a second predetermined threshold. In the example, upon comparing the delivered power with the second predetermined threshold and determining that the delivered power is less than the second predetermined threshold, the processor controls the HF RF generator 104 to increase supplied power of the RF signal 162 to calibrate the HF RF generator 104. To illustrate, to control the HF RF generator 104, the processor increases the power level sent previously within the recipe signal 156 to output an increased power level and sends the increased power level within a recipe signal RS2 via the transfer cable 150 to the HF RF generator 104.

Further, in the example, the processor of the process controller 116 identifies, based on the identity of the input I11, received within the digital signals 147 that the input I11 is coupled to the LF RF generator 106. In the example, the processor accesses a correspondence between the input I11 and the LF RF generator 106 from the memory device of the process controller 116. Also, in the example, the processor calculates delivered power from the forward and reverse powers at the input I11, and determines whether the delivered power satisfies a third predetermined threshold. In the example, upon comparing the delivered power with the third predetermined threshold and determining that the delivered power is less than the third predetermined threshold, the processor controls the LF RF generator 106 to increase supplied power of the RF signal 164 to calibrate the LF RF generator 106. To illustrate, to control the LF RF generator 106, the processor increases the power level sent previously within the recipe signal 158 to output an increased power level and sends the increased power level within a recipe signal RS3 via the transfer cable 152 to the LF RF generator 106. It should be noted that in the example, the processor sends the recipe signals RS1 through RS3 within a predetermined time window to the RF generators 102 through 106 to calibrate the RF generators 102 through 106 in the simultaneous manner, such as within the prearranged time period. To illustrate, the recipe signals RS1 through RS3 are sent at the same time or substantially at the same time. To further illustrate, the recipe signal RS2 or RS3 is sent within 1-10 nanoseconds before or after sending the recipe signal RS1.

In the example, the processor analyzes the first through seventh digital signals within a preset time window to facilitate calibration of the RF generators 102 through 106 within the prearranged time period. To illustrate, the processor identifies the identities of the inputs I1, I2, and I11, calculates the delivered powers from the forward and reverse powers at the inputs I1, I2, and I11, determines whether the delivered powers satisfy the first, second, and third predetermined thresholds, and controls the RF generators 102, 104, and 106 based on the determination within a preset time frame.

In the example, the DSP of each of the RF generators 102 through 106 stores the respective recipe signals RS1 through RS3 in the respective memory device of the RF generator. For example, the DSP of the RF generator 102 receives the recipe signal RS1 and stores the increased or decreased power level received within the recipe signal RS1 in the memory device of the RF generator 102, the DSP of the RF generator 104 receives the recipe signal RS2 and stores the increased or decreased power level received within the recipe signal RS2 in the memory device of the RF generator 104, and the DSP of the RF generator 106 receives the recipe signal RS3 and stores the increased or decreased power level received within the recipe signal RS3 in the memory device of the RF generator 106. Further, in the example, upon receiving a trigger signal, each of the RF generators 102 through 106 increases or decreases the respective power level of the respective RF signal 160, 162, or 164 to the respective increased or decreased power level. In this manner, the RF generators 102 through 104 are calibrated in the simultaneous manner, such as within the prearranged time period, when the RF signals 160, 162, and 164 are being generated at the same time.

The reception of the digital signals 147 facilitates determination of one or more faults in one or more components in the system 100. For example, one or more faults in any component of the system 100 are determined within a preset time period, such as simultaneously. To illustrate, upon determining that the delivered power of the RF signal 164 is less the third predetermined threshold and the delivered power of the RF signal 162 is below the second predetermined threshold, the processor of the process controller 116 determines that the edge ring 134 or the LF RF generator 106 or a combination thereof is faulty, and the HF RF generator 104 or the substrate support 126 or a combination thereof is faulty. As another example, upon determining that the delivered power of the RF signal 164 is less the third predetermined threshold, the delivered power of the RF signal 162 is less the second predetermined threshold, and the delivered power of the RF signal 160 is less that the first predetermined threshold, the processor of the process controller 116 determines that the edge ring 134 or the LF RF generator 106 or a combination thereof is faulty, and the HF RF generator 104 or the substrate support 126 or a combination thereof is faulty, and the LF RF generator 102 or the substrate support 126 of a combination thereof is faulty. As yet another example, faults in two or more of the RF generators 102, 104, and 106 are determined simultaneously. To illustrate, upon determining that delivered power of the RF signal 160 is below the first predetermined threshold, delivered power of the RF signal 162 is below the second predetermined threshold, and delivered power of the RF signal 164 is below the third predetermined threshold, the processor of the process controller 116 determines that all the RF generators 102, 104, and 106 have faults.

In one embodiment, upon comparing the delivered power generated from the measurement signals MS1 and MS2 does not satisfy the first predetermined threshold, the processor controls the RF generator 102, or the RF generator 104, or the RF generator 106, or a combination of two or more thereof until the first predetermined threshold is satisfied. Similarly, in the embodiment, upon comparing the delivered power generated from the measurement signals MS3 and MS4 does not satisfy the second predetermined threshold, the processor controls the RF generator 102, or the RF generator 104, or the RF generator 106, or a combination of two or more thereof until the second predetermined threshold is satisfied. Also, in the embodiment, upon comparing the delivered power generated from the measurement signals MS5 and MS6 does not satisfy the third predetermined threshold, the processor controls the RF generator 102, or the RF generator 104, or the RF generator 106, or a combination of two or more thereof until the third predetermined threshold is satisfied.

In an embodiment, the processor of the analytical controller 108 sends the TTL signal to the LF RF generator 102 via a transfer cable (not shown) and sends the TTL signal via another transfer cable (not shown) to the HF RF generator 104 to synchronize operations of the RF generators 102, 104, and 106. Moreover, the processor of the analytical controller 108 sends the TTL signal via the transfer cable 146 (FIG. 1) to the processor of the process controller 116.

In one embodiment, instead of not placing the substrate, a dummy substrate, such as a glass plate, is placed on the top surface of the substrate support 126.

In an embodiment, instead of two LF RF generators 102 and 106 and the HF RF generator 104, a single LF RF generator is used and two HF RF generators are used.

In one embodiment, instead of two LF RF generators 102 and 106 and the HF RF generator 104, two RF generators are used. For example, the system 100 includes the LF RF generators 102 and 106 without including the HF RF generator 104. As another example, the system 100 includes the LF RF generator 102 and the HF RF generator 104 without including the LF RF generator 106. As yet another example, the system 100 includes the LF RF generator 106 and the HF RF generator 104 without including the LF RF generator 102. The methods described herein apply to the two RF generators.

In an embodiment, in addition to the two LF RF generators 102 and 106 and the HF RF generator 104, one or more additional RF generators are used in the system 100. For example, in addition to the LF RF generator 106, an HF RF generator is coupled to another input of the match 112. Also, an RF sensor, such as the RF sensor 122, is coupled to the other input of the match 112. The methods described herein apply to the LF RF generators 102 and 106, the HF RF generator 104, and the one or more additional RF generators.

In one embodiment, in addition to the LF RF generator 102 and the HF RF generator 104, a middle frequency (MF) RF generator is coupled to an input of the match 110. An example of the MF RF generator is a generator having an operating frequency, such as a fundamental frequency, of 13.56 MHz or 27 MHz.

In one embodiment, instead of a power meter, a voltage sensor or a current sensor is used.

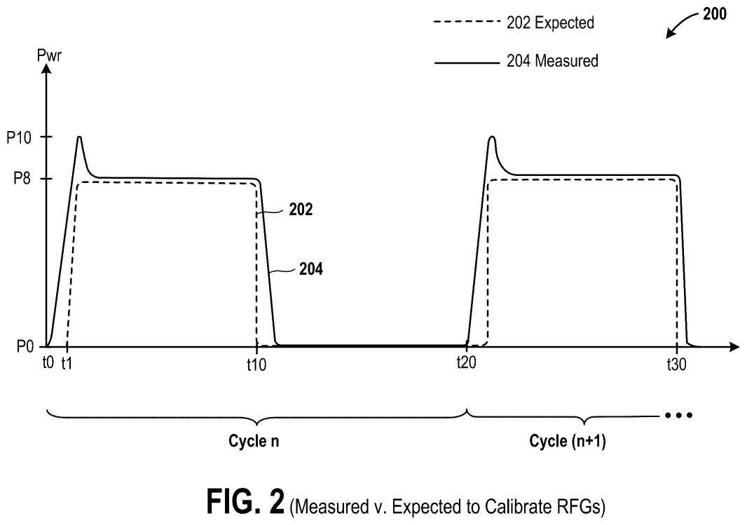

FIG. 2 is a graph 200 to illustrate a method for calibrating an RF generator, such as any of the RF generators 102, 104, or 106 (FIG. 1), or a combination thereof. The graph 200 plots a power level of an RF signal delivered by the RF generator versus time t. The power level is plotted on a y-axis and the time t is plotted on an x-axis.

The power levels range from a value P0 to a value P10 and the time t ranges from a time t0 to a time t30. The power level increases from the value P0 to the value P10 and the time t progresses from t0 to t30. The graph 200 includes a plot of an expected envelope 202 and another plot of a measured envelope 204. An example of an envelope, as used herein, is a peak-to-peak amplitude or a zero-to-peak amplitude.

A predetermined range from the expected envelope 202 is an example of the first, second, or third predetermined threshold. For example, when the plot 202 represents delivered power expected from the LF RF generator 102 and the plot 204 represents delivered power calculated from the measurement signals MS1 and MS2, a first predetermined range from the expected envelope 202 is an example of the first predetermined threshold. As another example, when the expected envelope 202 represents delivered power expected from the HF RF generator 104 and the plot 204 is represents delivered power calculated from the measurement signals MS3 and MS4, a second predetermined range from the expected envelope 202 is an example of the second predetermined threshold. As yet another example, when the expected envelope 202 represents delivered power expected from the LF RF generator 106 and the plot 204 represents delivered power calculated from the measurement signals MS5 and MS6, a third predetermined range from the expected envelope 202 is an example of the third predetermined threshold.

The processor of the process controller 116 stores multiple values of the expected envelope 202 in the memory device of the process controller 116. For example, a correspondence, such as a one-to-one relationship, is stored between each of the values of the expected envelope 202 and a respective one of the times t0 through t20 during each cycle of the clock signal. The cycles of the clock signal include a cycle n and a cycle (n+1), where n is an integer greater than zero.

During each cycle of the clock signal, the processor of the process controller 116 receives the measurement signals MS1 and MS2, and calculates measured delivered power from the measurement signals MS1 and MS2. For example, the measured delivered power is a difference between the measurement signals MS2 and MS1. An example of the measured delivered power is illustrated as the measured envelope 204.

The processor of the process controller 116 compares one or more values of the measured envelope 204 with corresponding one or more values of the expected envelope 202 for one or more of the times t0 through t20 to determine whether the measured envelope 204 satisfies a predetermined threshold, such as the first predetermined threshold, the second predetermined threshold, or the third predetermined threshold. For example, the processor of the process controller 116 compares a value of the measured envelope 204 at the time t1 with a value of the expected envelope 202 at the time t1 to determine whether the value of the measured envelope 204 is greater than or less than the pre-determined threshold. In the example, upon determining that the value of the measured envelope 204 is greater than the value of the expected envelope 202, the processor of the process controller 116 controls the RF generator to increase power delivered by the RF generator until the value of the measured envelope 204 is within a predetermined range, such as matches or within a predetermined percentage from, the value of the expected envelope 202. In this manner, the processor of the process controller 116 calibrates one or more of the RF generators 102 through 106.

In one embodiment, the processor of the process controller 116 receives the digital signals 147 and connects sample values of the digital signals 147 to generate the measured envelope 204.

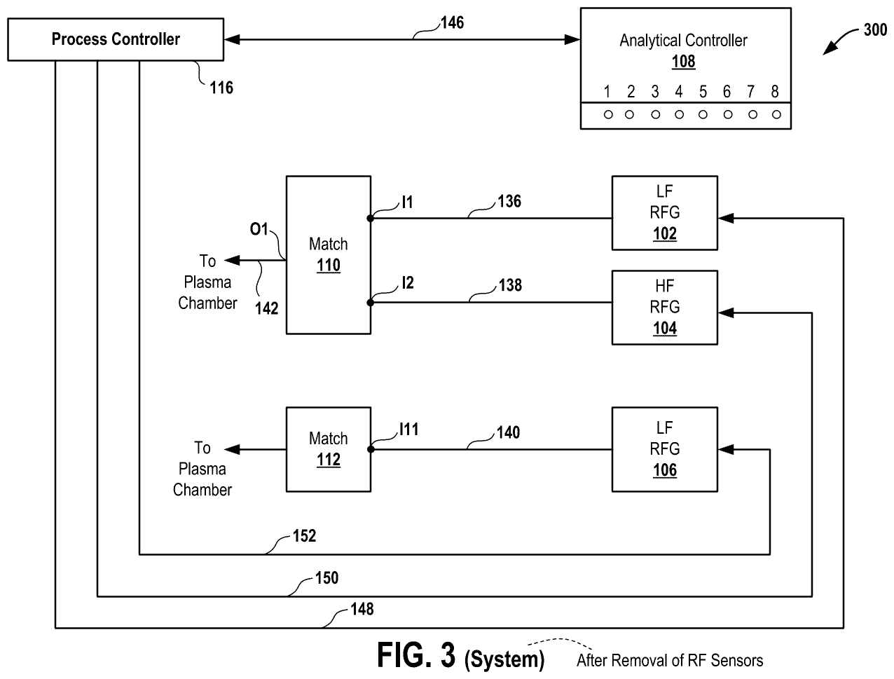

FIG. 3 is a diagram of an embodiment of a system 300 to illustrate a removal of the RF sensors 118 through 122 (FIG. 1) and the voltage sensor 124 (FIG. 1) from the system 100 after calibrating the RF generators 102 through 106. The system 300 includes the same components as that of the system 100 except that the system 300 does not include the RF sensors 118, 120, and 122, and the voltage sensor 124. For example, during processing of the substrate within the plasma chamber 114 (FIG. 1), the RF cable 136 is coupled to the input I1 without being coupled to the RF sensor 118. Also, in the example, the RF cable 138 is coupled to the input I2 without being coupled to the RF sensor 120, and the RF cable 140 is coupled to the input I11 without being coupled to the RF sensor 122. To illustrate, the RF cable 136 is directly coupled to the input I1 without being coupled to the input I1 via the RF sensor 118. As another illustration, the RF sensor 118 is decoupled, such as disconnected, from the input I1 to be removed from the system 100. Further, in the example, the output O1 is coupled via the RF transmission line 142 to the lower electrode 132 (FIG. 1) without being coupled to the voltage sensor 124. It should be noted that the system 300 includes the analytical controller 108. For example, the analytical controller 108 is coupled to the process controller 116.

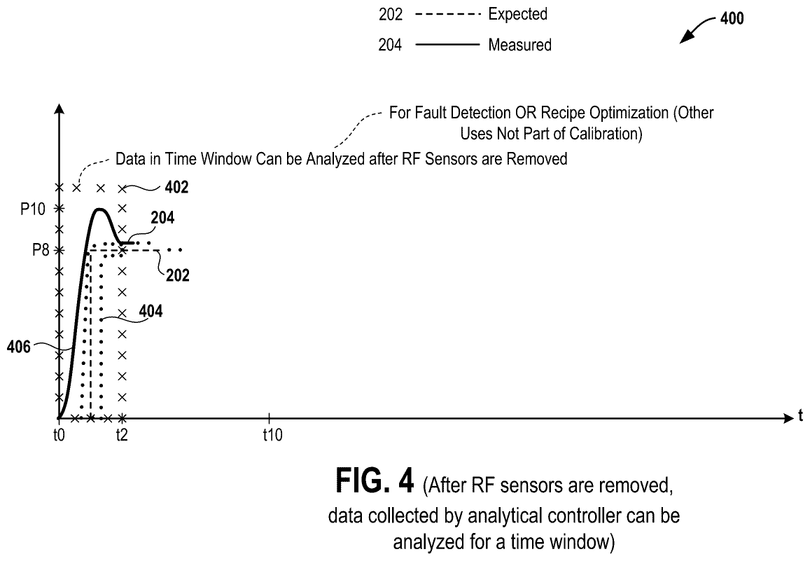

FIG. 4 is a graph 400 to illustrate an analysis by the processor of the process controller 116 (FIG. 1) of the measured information within the digital signals 147 received from the analytical controller 108. The measured information is analyzed for a predetermined time window 402. Moreover, the measured information is analyzed by the processor of the process controller 116 (FIG. 1) after calibrating two or more of the RF generators 102 through 106 during the prearranged time period. For example, the measured information is analyzed before processing the substrate S for recipe formation or during processing the substrate S for fault detection. The recipe formation is generation of recipe signals, such as the recipe signals RS1 through RS3, by the processor of the process controller 116. The graph 400 is the same as the graph 200 except in the graph 400, the plots 202 and 204 are shown for the predetermined time window 402. After two or more of the RF generators 102 through 106 (FIG. 1) are calibrated within the prearranged time period and after the RF sensors 118 through 122 and the voltage sensor 124 (FIG. 1) are removed from the system 100, the processor of the process controller 116 accesses a portion 404 of the expected envelope 202 and a portion 406 of the measured envelope 204 corresponding to the predetermined time window 402 from the memory device of the process controller 116, and compares the portion 404 with the portion 406 to modify the recipe signals RS1 through RS3 to achieve the recipe formation or for fault detection within the system 300. For example, the processor of the process controller 116 determines that there is a fault in the one or more components of the system 300 (FIG. 3) upon determining that one or more values of the portion 406 are not within a preset threshold, such as a preset range, from one or more values of the portion 404. To illustrate, the preset threshold is narrower and closer to the portion 404 compared to the predetermined range. In the illustration, both the preset and predetermined ranges extend around the portion 404.

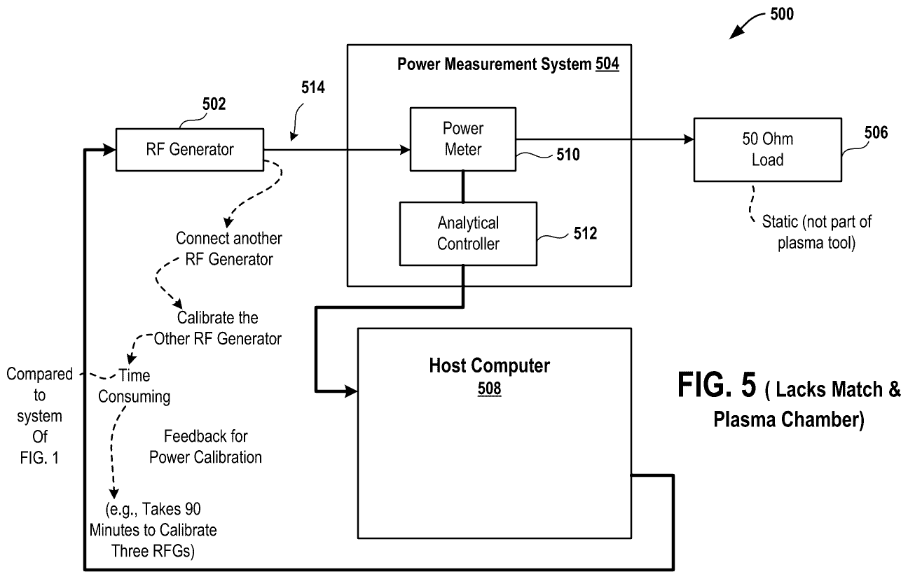

FIG. 5 is a diagram of an embodiment of a system 500 to illustrate that calibration of an RF generator 502 is more time consuming than the calibration of the RF generators 102 through 106 (FIG. 1) within the prearranged time period. An example of the RF generator 502 is any of the RF generators 102, 104, and 106 (FIG. 1). The system 500 includes the RF generator 502, a power measurement system 504, a 50 ohm load 506, and a host computer 508. An example of the 50 ohm load 506 is a combination of one or more resistors. To illustrate, the 50 ohm load 506 is not a plasma chamber. Examples of the host computer 508 include a desktop computer, a laptop computer, a smart phone, and a tablet.

The power measurement system 504 includes a power meter 510 and an analytical controller 512. The RF generator 502 is coupled to the power meter 510, which is coupled to the analytical controller 512. Also, the power meter 510 is coupled to the 50 ohm load 506 and the analytical controller 512 is coupled to the host computer 508. The host computer 508 is coupled to the RF generator 502. It should be noted that the system 500 lacks a match, such as the match 110 or the match 112 (FIG. 1).

The RF generator 502 generates an RF signal 514 and supplies the RF signal 514 to the power meter 510. The power meter 510 measures delivered power of the RF signal 514 to generate an analog measurement and sends the analog measurement to the analytical controller 512. The analytical controller 512 converts the analog measurement from an analog form to a digital form to output a digital measurement, and sends the digital measurement to the host computer 508.

The host computer 508 calibrates the RF generator 502 based on the digital measurement. After the RF generator 502 is calibrated, the RF generator 502 is disconnected from the power meter 510 and the host computer 508 and another RF generator (not shown) is connected in place of the RF generator 502. The other RF generator (not shown) is then calibrated in the same manner in which the RF generator 502 is calibrated. As such, the RF generator 502 and the other RF generator are calibrated sequentially, rather than within the prearranged time period. This is time consuming. For example, it takes more time to calibrate the RF generators 102 through 106 sequentially than within the prearranged time period, such as simultaneously. By calibrating the RF generators 102 through 106 within the prearranged time period and not sequentially, time is saved. Also, because the match is not used in the system 500, in case there is a fault in the match, the fault is not detected during calibration of the RF generator 502 or the other RF generator (not shown). In addition, because the 50 ohm load 506 is used in the system 500 instead of the plasma chamber 114 (FIG. 1), if there is a fault in any component of the plasma chamber 114, it is not detected based the analog measurement received from the power meter 510.

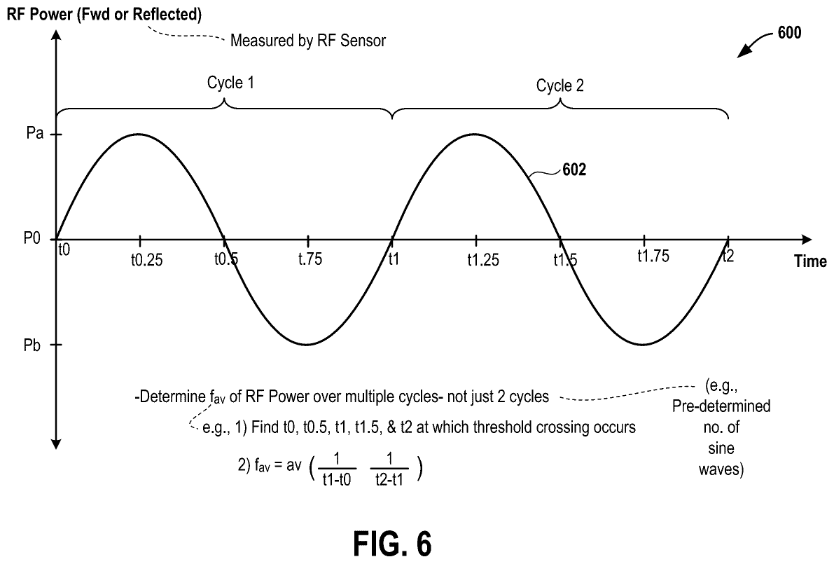

FIG. 6 is a graph 600 to illustrate a method for calculation of an average frequency fₐᵥ. The graph 600 plots power, such as forward power or reflected power or delivered power, of the RF generator, such as the RF generator 102 or 104 or 106 (FIG. 1), on a y-axis and the time t on an x-axis. The time t ranges from the time t0 to the time t2. As an example, the time t of the graph 600 indicates times at which power values of a measurement signal 602 are received by the analytical controller 108 (FIG. 1) from any of the sensors 118, 120, or 122 (FIG. 1). The power plotted on the graph 600 ranges from a power value Pb to a power value Pa. The values of power on the graph 600 increase from Pb to Pa. For example, the power value Pa is greater than the power value P0, which is greater than the power value Pb. An example of the power value P0 is a positive power value. Also, in the example, the power value Pa is a positive power value and the power value Pb is a positive power value.

A time period, such as a time period from the time t0 to the time t2, extends over a predetermined number of cycles of the measurement signal 602. Examples of the measurement signal 602 include the measurement signal MS1 or MS2 or MS3 or MS4 or MS5 or MS6 (FIG. 1). Another example of the measurement signal 600 is a delivered power signal computed from a set of the measurement signals MS2 and MS1, or a set of the measurement signals MS4 and MS3, or a set of the measurement signals MS6 and MS5. Examples of the predetermined number of cycles of the measurement signal 602 include two or more cycles, such as a cycle 1 and a cycle 2, of the measurement signal 602. To illustrate, the predetermined number of cycles include 5, 7, 10, or 20 cycles of the measurement signal 602.

As illustrated in the graph 600, the measurement signal 602 is sinusoidal and repeats during each cycle of the measurement signal 602. For example, during the cycle 1 of the measurement signal 602, the measurement signal 602 has the power value P0 at the time t0, reaches the power value Pa at the time t0.25, reaches the power value P0 at the time t0.5, reaches the power value Pb at the time t0.75, and reaches the power value P0 at the time t1. In the example, the measurement signal 602 repeats the power values P0, Pa, P0, Pb and P0 during the cycle 2 of the measurement signal 602.

The processor of the analytical controller 108 receives the measured information, such as the power values P0, Pa, P0, Pb and P0, within each cycle of the measurement signal 602. The processor of the analytical controller 108 determines, from the power values P0, Pa, P0, Pb and P0, times at which the power value P0 is output by the ADC of the analytical controller 108 to determine frequencies of the measurement signal 602 for each of the predetermined number of cycles of the measurement signal 602, and further determines an average frequency of the measurement signal 600 from the frequencies over the predetermined number of cycles of the measurement signal 602. For example, the processor of the analytical controller 108 identifies that the power value P0 is output from the ADC at each of the times t0, t0.5, and t1 during the cycle 1 of the measurement signal 602. Further, in the example, the processor of the analytical controller 108 determines that during the cycle 1 of the measurement signal 602, a positive threshold crossing of the measurement signal 600 occurs at each of the times t0 and t1 when the power value is P0. To illustrate, the processor of the analytical controller 108 determines that the positive threshold crossing occurs when a power value output from the ADC of the analytical controller 108 preceding to the power value P0 is less than the power value P0 and a power value output from the ADC of the analytical controller 108 immediately after the power value P0 is greater than the power value P0. Moreover, in the example, the processor of the analytical controller 108 identifies that the power value P0 is output by the ADC at each of the times t1, t1.5 and t2 and further determines that a positive threshold crossing occurs at each of the times t1 and t2 during the cycle 2. Further, in the example, the processor of the analytical controller 108 calculates an inverse of a difference between the times t1 and t0 at which the positive threshold crossing occurs during the cycle 1 of the measurement signal 602 to determine a first frequency of the measurement signal 600 for the cycle 1 of the measurement signal 600. In the example, the processor of the analytical controller 108 further calculates an inverse of a difference between the times t2 and t1 at which the positive threshold crossing occurs during the cycle 2 of the measurement signal 602 to determine a second frequency of the measurement signal 600 for the cycle 2 of the measurement signal 600. Also, in the example, the processor of the analytical controller 108 computes an average of the first and second frequencies to determine the average frequency for the predetermined number of cycles of the measurement signal 602.

In an embodiment, instead of the measurement signal 602 being a sine wave signal, the measurement signal 602 is a periodic signal. For example, the measurement signal 602 has another shape that is periodic.

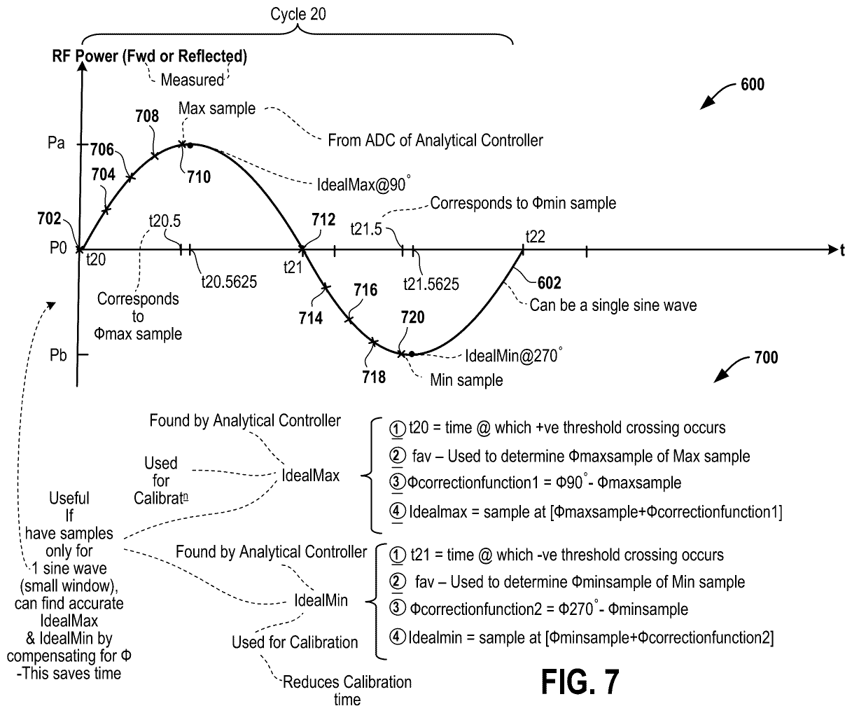

FIG. 7 is a diagram to illustrate a method 700 for determining an ideal maximum amplitude and an ideal minimum amplitude of the measurement signal 602 by using the average frequency. The ideal maximum amplitude is an example of an ideal amplitude value and the ideal minimum amplitude is an example of an ideal amplitude value. The method 700 corrects an error by the ADC of the analytical controller 108 in converting the measurement signal 602 from the analog format to the digital format. The graph 600 is illustrated in FIG. 7 starting at a time t20 and ending at a time t22. The time t progresses from the time t2 (FIG. 6) to the time t20 and from the time t20 to the time t22. It should be noted that the method 700 is executed during calibration the RF generators 102, 106, and 106 within the prearranged time period.

The method 700 is executed by the processor of the analytical controller 108 (FIG. 1). The ADC of the analytical controller 108 outputs multiple digital samples 702, 704, 706, 708, and 710, which are sample values, of the measurement signal 602 during a first half of a cycle 20 of the measurement signal 602. The first half of the cycle 20 is a positive half of the cycle 20. The cycle 20 occurs after the predetermined number of cycles of the measurement signal 602. However, there is an error in outputting the digital sample 710. Instead of outputting an IdealMax sample, the digital sample 710 is output from the ADC.

In the method 700, the processor of the analytical controller 108 determines the time t20 as a time at which a positive threshold crossing occurs. For example, the processor of the analytical controller 108 determines that the positive threshold crossing occurs when a power value output from the ADC of the analytical controller 108 preceding to the power value P0 is less than the power value P0 and a power value output from the ADC immediately after the power value P0 is greater than the power value P0. Moreover, in the example, the processor of the analytical controller 108 identifies from the correspondence information, that the power value P0 is output from the ADC at the time t20 of the positive threshold crossing during the cycle 20.

Continuing with the method 700, the processor of the analytical controller 108 applies the average frequency fₐᵥ to the time t20 at which the positive threshold crossing occurs to determine a phase ϕₘₐₓₛₐₘₚₗₑ of the digital sample 710, which has a maximum value during the cycle 20. For example, the processor of the analytical controller 108 determines that from the digital samples output from the ADC during the cycle 20, the digital sample 710 has a maximum value or a maximum amplitude. In the example, based on the average frequency fₐᵥ, the processor of the analytical controller 108 calculates a distance from the time t20 at which the positive threshold crossing occurs during the cycle 20 to the time t20.5 at which the digital sample 710 having the maximum amplitude is output from the ADC. Further, in the example, the time t20.5 is the phase ϕₘₐₓₛₐₘₚₗₑ of the digital sample 710.

Also, in the method 700, the processor of the analytical controller 108 determines a phase correction function ϕcorrectionfunction1 from the phase ϕₘₐₓₛₐₘₚₗₑ of the digital sample 710. For example, the processor of the analytical controller 108 identifies that ideally a maximum amplitude of the measurement signal 602 occurs at a first predetermined phase, such as a 90 degree phase ϕ90° or a first predefined phase. Further, in the example, the processor of the analytical controller 108 calculates an absolute difference between the first predetermined phase and the phase ϕₘₐₓₛₐₘₚₗₑ of the digital sample 710 and the absolute difference is the phase correction function ϕcorrectionfunction1. In the example, the first predefined phase is other than the 90 degree phase.

In the method 700, the processor of the analytical controller 108 computes a sum of the phase ϕₘₐₓₛₐₘₚₗₑ of the digital sample 710 and the phase correction function ϕcorrectionfunction1. Further, in the method 700, the processor of the analytical controller 108 determines an ideal maximum amplitude IdealMax of the measurement signal 602 that occurs at a first total phase, which is the sum of the phase ϕₘₐₓₛₐₘₚₗₑ of the digital sample 710 and the phase correction function ϕcorrectionfunction1. For example, the processor of the analytical controller 108 determines that the digital sample 710 does not have the ideal maximum amplitude. In the example, the processor of the analytical controller 108 accesses the measurement signal 602 in the analog format from the memory device of the analytical controller 108 and identifies the ideal maximum amplitude IdealMax that is received by the ADC from one of the RF sensors 118 through 122 (FIG. 1) at the first total phase.

The processor of the analytical controller 108 sends the ideal maximum amplitude IdealMax instead of the digital sample 710 to the processor of the process controller 116 via the transfer cable 146. For example, during the calibration of the RF generators 102, 104, and 106 within the prearranged time period, the processor of the analytical controller 108 replaces the digital sample 710 to be sent within the digital signals 147 to the process controller 116 with the ideal maximum amplitude IdealMax and sends the IdealMax within the digital signals 147 to the process controller 116.

The processor of the process controller 116 determines whether one or more of the RF generators 102, 104, and 106 are to be calibrated based on the ideal maximum amplitude IdealMax within the prearranged time period and controls the one or more of the RF generators 102, 104, and 106 to calibrate the one or more of the RF generators 102, 104, and 106. For example, in case the ideal maximum amplitude IdealMax is of the measured signal MS2 from the RF generator 102, the processor of the process controller 116 calculates delivered power from the ideal maximum amplitude IdealMax and a corresponding digital value of the measured signal MS1 at the first sum phase. In the example, the processor of the process controller 116 controls the RF generator 102 based on the delivered power. To illustrate, upon determining that the delivered power is less than the first predetermined threshold, the processor of the process controller 116 controls the RF generator 102 to increase power supplied by the RF generator 102 until the delivered power is within the first predetermined threshold. In the illustration, the processor of the process controller 116 sends an increase in an amount of power to be supplied by the RF generator 102 within the recipe signal RS1 (FIG. 1) to the RF generator 102 via the transfer cable 154 (FIG. 1). In the illustration, upon receiving the increase in the amount of power, the RF generator 102 generates an RF signal having the increased amount of power.

The ADC of the analytical controller 108 outputs multiple digital samples 712, 714, 716, 718, and 720 of the measurement signal 602 during a second half, such as a negative half, of the cycle 20 of the measurement signal 602. However, there is an error in outputting the digital sample 720. Instead of outputting an IdealMin sample, the digital sample 720 is output from the ADC.

In the method 700, the processor of the analytical controller 108 determines the time t21 as a time at which a negative threshold crossing occurs. For example, the processor of the analytical controller 108 determines that the negative threshold crossing occurs when a power value output from the ADC of the analytical controller 108 preceding to the power value P0 is greater than the power value P0 and a power value output from the ADC immediately after the power value P0 is less than the power value P0. Moreover, in the example, the processor of the analytical controller 108 identifies from the correspondence information, that the power value P0 is output from the ADC at the time t21 of the negative threshold crossing during the cycle 20.

Continuing with the method 700, the processor of the analytical controller 108 applies the average frequency fₐᵥ to the time t21 of the negative threshold crossing to determine a phase ϕₘᵢₙₛₐₘₚₗₑ of the digital sample 720, which has a minimum value during the cycle 20. For example, the processor of the analytical controller 108 determines that from the digital samples output from the ADC during the cycle 20, the digital sample 720 has a minimum value or a minimum amplitude. In the example, based on the average frequency fₐᵥ, the processor of the analytical controller 108 calculates a distance from the time t21 at which the negative threshold crossing occurs during the cycle 20 to the time t21.5 at which the digital sample 720 having the minimum amplitude is output from the ADC. Further, in the example, the time t21.5 is the phase ϕₘᵢₙₛₐₘₚₗₑ of the digital sample 720.

Also, in the method 700, the processor of the analytical controller 108 determines a phase correction function ϕcorrectionfunction2 from the phase ϕₘᵢₙₛₐₘₚₗₑ of the digital sample 720. For example, the processor of the analytical controller 108 identifies that ideally a minimum amplitude of the measurement signal 602 occurs at a second predetermined phase, such as a 270 degree phase ϕ270° or a second predefined phase. Further, in the example, the processor of the analytical controller 108 calculates an absolute difference between the second predetermined phase and the phase ϕₘᵢₙₛₐₘₚₗₑ of the digital sample 720 and the absolute difference is the phase correction function ϕcorrectionfunction2. In the example, the second predefined phase is other than the 270 degree phase.

In the method 700, the processor of the analytical controller 108 calculates a sum of the phase ϕₘᵢₙₛₐₘₚₗₑ of the digital sample 720 and the phase correction function ϕcorrectionfunction2. Moreover, in the method 700, the processor of the analytical controller 108 determines an ideal minimum amplitude IdealMin of the measurement signal 602 that occurs at a second total phase, which is the sum of the phase ϕₘᵢₙₛₐₘₚₗₑ of the digital sample 720 and the phase correction function ϕcorrectionfunction2. For example, the processor of the analytical controller 108 determines that the digital sample 720 does not have the ideal minimum amplitude. In the example, the processor of the analytical controller 108 accesses the measurement signal 602 in the analog format from the memory device of the analytical controller 108 and identifies the ideal minimum amplitude IdealMin that is received by the ADC from one of the RF sensors 118 through 122 at the second total phase.

The processor of the analytical controller 108 sends the ideal minimum amplitude IdealMin instead of the digital sample 720 to the processor of the process controller 116 via the transfer cable 146. For example, during the calibration of the RF generators 102, 104, and 106 within the prearranged time period, the processor of the analytical controller 108 replaces the digital sample 720 to be sent within the digital signals 147 to the process controller 116 with the ideal minimum amplitude IdealMin and sends the IdealMin within the digital signals 147 to the process controller 116.

The processor of the process controller 116 determines whether one or more of the RF generators 102, 104, and 106 are to be calibrated within the prearranged time period based on the ideal minimum amplitude IdealMin and controls the one or more of the RF generators 102, 104, and 106. For example, in case the ideal minimum amplitude IdealMin is of the measured signal MS2 from the RF generator 102, the processor of the process controller 116 calculates delivered power from the ideal minimum amplitude IdealMin and a corresponding digital value of the measured signal MS1 at the second sum phase. In the example, the processor of the process controller 116 controls the RF generator 102 based on the delivered power. As such, when a single cycle, such as the cycle 20, is used to determine the first and second total phases, as described in the examples above, there is a reduction in time for calibrating or controlling the RF generator 102.

In one embodiment, the predetermined number of cycles and the cycle 20 of the measurement signal 602 occur during a cycle of another measurement signal. For example, when the measurement signal 602 is an example of the measurement signal MS4, the other measurement signal is an example of the measurement signal MS2. In the example, the predetermined number of cycles and the cycle 20 of the measurement signal MS4 occur during a cycle, such as a single cycle, of the measurement signal MS2. In the example, the measurement signal MS4 has the high frequency and the measurement signal MS2 has the low frequency. Further, in the example, the low frequency is also of the RF signal 160 and the high frequency is of the RF signal 162.

In an embodiment, an example of the positive threshold crossing is a constant value, such as a positive value. Moreover, in the embodiment, an example of the negative threshold crossing is the constant value.

In an embodiment, a digital value is sometimes referred to herein as a sample point or a digital sample or a digital sample value.

In one embodiment, the method 700 is executed after calibrating the RF generators 102, 106, and 106 within the prearranged time period. For example, the method 700 is executed during processing of the substrate within the plasma chamber 114 (FIG. 1).

In an embodiment, the method 700 is equally applicable for determining an ideal amplitude value, which is other than the ideal maximum amplitude and the ideal minimum amplitude. For example, the method 700 is equally applicable to determining the ideal amplitude value at a phase other than 90 degrees or 270 degrees. To illustrate, the method 700 is equally applicable to determining the ideal amplitude value at a phase other than 80 degrees or 170 degrees.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A system for calibrating radio frequency (RF) generators, comprising:
a first RF generator coupled via a first RF cable to a first input of an impedance matching circuit;
a second RF generator coupled via a second RF cable to a second input of the impedance matching circuit;
wherein the first input of the impedance matching circuit is configured to be coupled to a first RF sensor,
wherein the second input of the impedance matching circuit is configured to be coupled to a second RF sensor,
a process controller; and
an analytical controller coupled to the process controller, wherein the analytical controller is configured to be coupled to the first and second RF sensors,
wherein the analytical controller is configured to receive a plurality of analog measurement signals from the first and second RF sensors to output a plurality of digital signals,
wherein the process controller is configured to receive the plurality of digital signals to calibrate the first and second RF generators.

2. The system of claim 1, wherein the first and second inputs of the impedance matching circuit are configured to be coupled to the first and second RF sensors during the same time period.

3. The system of claim 1, wherein the plurality of digital signals include a first set of digital signals received from the first RF sensor and a second set of digital signals received from the second RF sensor, wherein the process controller is configured to analyze the first and second sets of digital signals to calibrate the first and second RF generators within a prearranged time period.

4. The system of claim 3, wherein to calibrate the first and second digital signals within the prearranged time period, the processor controller is configured to compare:
a first value of measured RF power calculated based on the first set of digital signals with a first predetermined threshold of RF power of operation of the first RF generator;
a second value of measured RF power calculated based on the second set of digital signals with a second predetermined threshold of RF power of operation of the second RF generator, and
wherein to calibrate the first and second RF generators within the prearranged time period, the process controller is configured to:
control the first RF generator, or the second RF generator, or a combination thereof to achieve the first predetermined threshold upon determining that the first value of measured RF power does not satisfy the first predetermined threshold; and
control the first RF generator, or the second RF generator, or the combination thereof to achieve the second predetermined threshold upon determining that the second value of measured RF power does not satisfy the second predetermined threshold.

5. The system of claim 1, wherein the first and second RF sensors are configured to be decoupled from the first and second inputs of the impedance matching circuit after the first and second RF generators are calibrated, wherein the analytical controller continues to be coupled to the process controller after the first and second RF generators are calibrated, wherein the process controller is configured to:
compare a portion of measured power generated from a set of the plurality of digital signals with a preset threshold;
determine that the portion of measured power lies outside the preset threshold based on the comparison; and
modify RF power of the first RF generator, or the second RF generator, or a combination thereof upon determining that the portion of measured power lies outside the preset threshold.

6. The system of claim 1, wherein the analytical controller is configured to:
determine an average frequency of one of the plurality of analog measurement signals, wherein the average frequency is determined for a predetermined number of cycles of the one of the plurality of analog measurement signals;
determine, for a cycle of the one of the plurality of analog measurement signals, a time of occurrence of a first threshold crossing of the one of the plurality of analog measurement signals, wherein the cycle occurs after the predetermined number of cycles;
determine, based on the average frequency and the time of occurrence of the first threshold crossing, a first phase of a first sample point, wherein the first sample point is a first measured value of the one of the plurality of analog measurement signals during a first half of the cycle;
determine a first correction function from a first predetermined phase and the first phase; and
determine a first ideal amplitude value of the one of the plurality of analog measurement signals based on the first correction function.

7. The system of claim 6, wherein the analytical controller is configured to:
determine, for the cycle of the one of the plurality of analog measurement signals, a time of occurrence of a second threshold crossing of the one of the plurality of analog measurement signals;
determine, based on the average frequency and the time of occurrence of the second threshold crossing, a second phase of a second sample point, wherein the second sample point is a second measured value of the one of the plurality of analog measurement signals during a second half of the cycle;
determine a second correction function from a second predetermined phase and the second phase; and
determine a second ideal amplitude value of the one of the plurality of analog measurement signals based on the second correction function.

8. The system of claim 7, wherein the analytical controller is configured to provide the first ideal amplitude value and the second ideal amplitude value to the process controller, wherein the process controller is configured to calibrate one or more of the first and second RF generators based on the first ideal amplitude value and the second ideal amplitude value.

9. The system of claim 1, wherein the first and second RF generators are not calibrated sequentially, wherein the impedance matching circuit is coupled to a plasma chamber to calibrate the first and second RF generators.

10. A method for calibrating radio frequency (RF) generators, comprising:
receiving a plurality of analog measurement signals from a plurality of RF sensors to output a plurality of digital signals, wherein the plurality of analog signals are received by an analytical controller; and
calibrating, in a simultaneous manner, the RF generators based on the plurality of digital signals, wherein the RF generators are calibrated by a process controller.

11. The method of claim 10, wherein the plurality of RF sensors include a first RF sensor and a second RF sensor, wherein the plurality of RF generators include a first RF generator and a second RF generator, wherein the first RF generator is coupled via a first RF cable to a first input of an impedance matching circuit, wherein the second RF generator is coupled via a second RF cable to a second input of the impedance matching circuit, wherein the first and second inputs of the impedance matching circuit are coupled to the first and second RF sensors during the same time period.

12. The method of claim 10, wherein the plurality of RF sensors include a first RF sensor and a second RF sensor, wherein the plurality of digital signals include a first set of digital signals received from the first RF sensor and a second set of digital signals received from the second RF sensor, the method comprising analyzing the first and second sets of digital signals to calibrate the first and second RF generators within a prearranged time period.

13. The method of claim 12, wherein said analyzing the first and second sets of digital signals includes:
comparing a first value of measured RF power calculated based on the first set of digital signals with a first predetermined threshold of RF power of operation of a first RF generator;
comparing a second value of measured RF power calculated based on the second set of digital signals with a second predetermined threshold of RF power of operation of a second RF generator,
wherein said calibrating the RF generators includes calibrating the first and second RF generators within the prearranged time period, wherein said calibrating the first and second RF generators within the prearranged time period includes:
controlling the first RF generator, or the second RF generator, or a combination thereof to achieve the first predetermined threshold of RF power of operation upon determining that the first value of measured RF power does not satisfy the first predetermined threshold;
controlling the first RF generator, or the second RF generator, or a combination thereof to achieve the second predetermined threshold of RF power of operation upon determining that the second value of measured RF power does not satisfy the second predetermined threshold.

14. The method of claim 10, wherein the plurality of RF sensors include a first RF sensor and a second RF sensor, wherein the plurality of RF generators include a first RF generator and a second RF generator, wherein the first RF generator is coupled via a first RF cable to a first input of an impedance matching circuit, and the second RF generator is coupled via a second RF cable to a second input of the impedance matching circuit, wherein the first and second RF sensors are configured to be decoupled from the first and second inputs of the impedance matching circuit after the first and second RF generators are calibrated, wherein the analytical controller continues to be coupled to the process controller after the first and second RF generators are calibrated, the method further comprising:
comparing a portion of measured power generated from a set of the plurality of digital signals with a preset threshold;
determining that the portion of measured power lies outside the preset threshold based on the comparison; and
modifying RF power of one of the first RF generator or the second RF generator or a combination thereof upon determining that the portion of measured power lies outside the preset threshold.

15. The method of claim 10, further comprising:
determining an average frequency of one of the plurality of analog measurement signals, wherein the average frequency is determined for a predetermined number of cycles of the one of the plurality of analog measurement signals;
determining, for a cycle of the one of the plurality of analog measurement signals, a time of occurrence of a first threshold crossing of the one of the plurality of analog measurement signals, wherein the cycle occurs after the predetermined number of cycles;
determining, based on the average frequency and the time of occurrence of the first threshold crossing, a first phase of a first sample point, wherein the first sample point is a first measured value of the one of the plurality of analog measurement signals during a first half of the cycle;
determining a first correction function from a first predetermined phase and the first phase; and
determining a first ideal amplitude value of the one of the plurality of analog measurement signals based on the first correction function.

16. The method of claim 15, further comprising:
determining, for the cycle of the one of the plurality of analog measurement signals, a time of occurrence of a second threshold crossing of the one of the plurality of analog measurement signals;
determining, based on the average frequency and the time of occurrence of the second threshold crossing, a second phase of a second sample point, wherein the second sample point is a second measured value of the one of the plurality of analog measurement signals during a second half of the cycle;
determining a second correction function from a second predetermined phase and the second phase; and
determining a second ideal amplitude value of the one of the plurality of analog measurement signals based on the second correction function.

17. The method of claim 16, further comprising:
providing, by the analytical controller, the first ideal amplitude value and the second ideal amplitude value to the process controller, wherein one or more of the RF generators are calibrated based on the first ideal amplitude value and the second ideal minimum value.

18. The method of claim 10, wherein the plurality of RF generators include a first RF generator and a second RF generator, wherein the first RF generator is coupled via a first RF cable to a first input of an impedance matching circuit, wherein the second RF generator is coupled via a second RF cable to a second input of the impedance matching circuit, wherein the first and second RF generators are not calibrated sequentially, wherein the impedance matching circuit is coupled to a plasma chamber to calibrate the first and second RF generators.

19. A method for determining ideal amplitude values, comprising:
determining an average frequency of one of a plurality of analog measurement signals, wherein the average frequency is determined for a predetermined number of cycles of the one of the plurality of analog measurement signals;
determining, for a cycle of the one of the plurality of analog measurement signals, a time of occurrence of a first threshold crossing of the one of the plurality of analog measurement signals, wherein the cycle occurs after the predetermined number of cycles;
determining, based on the average frequency and the time of occurrence of the first threshold crossing, a first phase of a first sample point, wherein the first sample point is a first measured value of the one of the plurality of analog measurement signals during a first half of the cycle;
determining a first correction function from a first predetermined phase and the first phase;
determining a first ideal amplitude value of the one of the plurality of analog measurement signals based on the first correction function; and
controlling a first radio frequency (RF) generator based on the first ideal amplitude value.

20. The method of claim 19, further comprising:
determining, for the cycle of the one of the plurality of analog measurement signals, a time of occurrence of a second threshold crossing of the one of the plurality of analog measurement signals;
determining, based on the average frequency and the time of occurrence of the second threshold crossing, a second phase of a second sample point, wherein the second sample point is a second measured value of the one of the plurality of analog measurement signals during a second half of the cycle;
determining a second correction function from a second predetermined phase and the second phase;
determining a second ideal amplitude value of the one of the plurality of analog measurement signals based on the second correction function; and
controlling the first RF generator based on the second ideal amplitude value.

21. The method of claim 19, wherein the predetermined number of cycles and the cycle of the one of the plurality of analog measurement signals occur during a cycle of an RF signal generated by a second RF generator, wherein the second RF generator has a lower frequency of operation than a frequency of operation of the first RF generator.
